(19) United States
(12) Patent Application Publication
(10) Pub. No.: US 2012/0126283 A1
(43) Pub. Date: May 24, 2012

(54) HIGH POWER, HIGH EFFICIENCY AND LOW EFFICIENCY DROOP III-NITRIDE LIGHT-EMITTING DIODES ON SEMIPOLAR SUBSTRATES

(75) Inventors: Yuji Zhao, Goleta, CA (US); Junichi Sonoda, Kanagawa (JP); Chih-Chien Pan, Goleta, CA (US); Shinichi Tanaka, Santa Barbara, CA (US); Steven P. DenBaars, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/283,259

(22) Filed: Oct. 27, 2011

Related U.S. Application Data
(60) Provisional application No. 61/407,357, filed on Oct. 27, 2010.

(51) Int. Cl. H01L 33/02

(52) U.S. Cl. 257/103; 438/46; 257/E33.023

(57) ABSTRACT

A III-nitride light emitting diode grown on a semipolar {20-2-1} plane of a substrate and characterized by high power, high efficiency and low efficiency droop.

### CROSS REFERENCE TO RELATED APPLICATION

This application claims the benefit under 35 U.S.C. Section 119(e) of the following co-pending and commonly-assigned application:

U.S. Provisional Patent Application Ser. No. 61/407,357, filed on Oct. 27, 2010, by Yuji Zhao, Junichi Sonoda, Chih-Chien Pan, Shinichi Tanaka, Steven P. DenBaars, and Shuji Nakamura, entitled “HIGH POWER, HIGH EFFICIENCY AND LOW EFFICIENCY DROOP III-NITRIDE LIGHT-EMITTING DIODES ON SEMIPOLAR {20-2-1} SUBSTRATES,” attorneys' docket number 30794.403-US-P1 (2011-258-1);

which application is incorporated by reference herein.

This application is related to the following co-pending and commonly-assigned applications:

U.S. Utility patent application Ser. No. ______, filed on Oct. 27, 2011, by Shuji Nakamura, Steven P. DenBaars, Shinichi Tanaka, Junichi Sonoda, Hung Tse Chen, and Chih-Chien Pan, entitled “LIGHT EMITTING DIODE FOR DROOP IMPROVEMENT,” attorneys' docket number 30794.394-US-U1 (2011-169-2), which application claims the benefit under 35 U.S.C. Section 119(e) of co-pending and commonly-assigned U.S. Provisional Patent Application Ser. No. 61/407,343, filed on Oct. 27, 2010, by Shuji Nakamura, Steven P. DenBaars, Shinichi Tanaka, Junichi Sonoda, Hung Tse Chen, and Chih-Chien Pan, entitled “LIGHT EMITTING DIODE FOR DROOP IMPROVEMENT,” attorneys' docket number 30794.394-US-P1 (2011-169-1); U.S. Utility Patent Application Serial No. ______, filed on Oct. 27, 2011, by Roy B. Chung, Changseok Han, Steven P. DenBaars, James S. Speck, and Shuji Nakamura, entitled “METHOD FOR REDUCTION OF EFFICIENCY DROOP USING AN (Al,In,Ga)N/Al(x)In(1−x)N SUPERLATTICE ELECTRON BLOCKING LAYER IN NITRIDE BASED LIGHT EMITTING DIODES,” attorneys' docket number 30794.399-US-U1 (2011-230-2), which application claims the benefit under 35 U.S.C. Section 119(e) of co-pending and commonly-assigned U.S. Provisional Patent Application Ser. No. 61/407,362, filed on Oct. 27, 2010, by Roy B. Chung, Changseok Han, Steven P. DenBaars, James S. Speck, and Shuji Nakamura, entitled “METHOD FOR REDUCTION OF EFFICIENCY DROOP USING AN (Al,In,Ga)N/Al(x)In(1−x)N SUPERLATTICE ELECTRON BLOCKING LAYER IN NITRIDE BASED LIGHT EMITTING DIODES,” attorneys' docket number 30794.399-US-P1 (2011-230-1);

U.S. Provisional Patent Application Ser. No. 61/495,829, filed on Jun. 10, 2011, by Shuji Nakamura, Steven P. DenBaars, Shinichi Tanaka, Daniel F. Feezell, Yuji Zhao, and Chih-Chien Pan, entitled “LOW DROOP LIGHT EMITTING DIODE STRUCTURE ON GALLIUM NITRIDE SEMIPOLAR {20-2-1} SUBSTRATES,” attorneys' docket number 30794.415-US-P1 (2011-832-1); and

U.S. Provisional Patent Application Ser. No. 61/495,840, filed on Jun. 10, 2011, by Shuji Nakamura, Steven P. DenBaars, Daniel F. Feezell, Chih-Chien Pan, Yuji Zhao, and Shinichi Tanaka, entitled “HIGH EMISSION POWER AND LOW EFFICIENCY DROOP SEMIPOLAR {20-2-1} BLUE LIGHT EMITTING DIODES,” attorneys' docket number 30794.416-US-P1 (2011-833-1); all of which applications are incorporated by reference herein.

### BACKGROUND OF THE INVENTION

1. Field of the Invention

The invention is related generally to the field of light emitting diodes, and more particularly, to III-nitride light emitting diodes (LEDs) grown on semipolar {20-2-1} substrates and characterized by high power, high efficiency and low efficiency droop.

2. Description of the Related Art

Existing (Al,Ga,In)N LEDs are typically grown on polar {0001}, nonpolar {10-10} and {11-20}, or semipolar {11-22} and {10-1-1} planes. LEDs grown on polar and semipolar planes suffer from polarization related electric fields in the quantum wells that degrade device performance. While nonpolar {10-10} and {11-20} devices are free from polarization related effects, incorporation of high Indium concentrations in {10-10} devices and high quality crystal growth of {11-20} devices have been shown to be difficult to achieve.

However, devices grown on a {20-2-1} plane, which is a semipolar plane comprised of a miscut from the m-plane in the c-direction, should have minimal polarization related electric fields in the quantum wells as compared to conventional semipolar planes (i.e., {11-22}, {10-1-1}, etc.). Moreover, an LED grown on the {20-2-1} plane should provide a lower QCSE (quantum confined Stark effect) induced, injection current dependent, blue shift in its output wavelength, as well as increased oscillator strength, leading to higher material gain, etc., as compared to a c-plane LEDs and other nonpolar or semipolar devices. In addition, LEDs grown along the semipolar {20-2-1} plane, are likely to show better performance at long wavelengths, since semi-polar planes are believed to incorporate Indium more easily. Finally, an LED grown on the {20-2-1} plane should exhibit reduced efficiency droop, which is a phenomenon that describes the decrease in the external quantum efficiency (EQE) with increasing injection current.

Thus, there is a need in the art for improved methods of fabricating III-nitride LEDs. The present invention satisfies this need.

### SUMMARY OF THE INVENTION

To overcome the limitations in the prior art described above, and to overcome other limitations that will become apparent upon reading and understanding the present specification, the present invention discloses III-nitride LEDs grown on semipolar {20-2-1} substrates and characterized by high power, high efficiency and low efficiency droop.

### BRIEF DESCRIPTION OF THE DRAWINGS

Referring now to the drawings in which like reference numbers represent corresponding parts throughout:

FIG. 1 is a schematic of a prototype LED device fabricated according to one embodiment of the present invention.

FIG. 2 is a flow chart that describes a method for fabricating an LED according to one embodiment of the present invention.

FIG. 3(a) is a graph of the L-I (light output power vs. current) and EQE-I (external quantum efficiency vs. current) characteristics of the prototype LED device of FIG. 1.

FIG. 3(b) is a graph of I-V (current v. voltage) characteristics of the prototype LED device of FIG. 1.

FIG. 4 is a graph of the electroluminescence (EL) spectrum for green light emitting semipolar {20-2-1} and {20-21} LEDs.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes (Al,Ga,In)N based LEDs grown on semipolar {20-2-1} planes. The benefits of the present invention include improved LED performance for display applications, lighting, illumination, water purification, etc.

The inventors have fabricated a working prototype of a blue light emitting LED on a {20-2-1} substrate that yielded 30 mW light output power and 54.7% external quantum efficiency (EQE) at a driving current of 20 mA, which are higher values than any other LEDs grown on existing nonpolar or semipolar planes, and are comparable to the best state-of-art c-plane devices.

Moreover, the higher critical thickness of strained (Al,Ga,In)N alloy layers epitaxially grown on semipolar GaN substrates means that thicker quantum wells can be employed to help reduce effective carrier density in the quantum wells (reducing Auger-type losses and efficiency droop) and can facilitate low transparency carrier density.

Device Structure

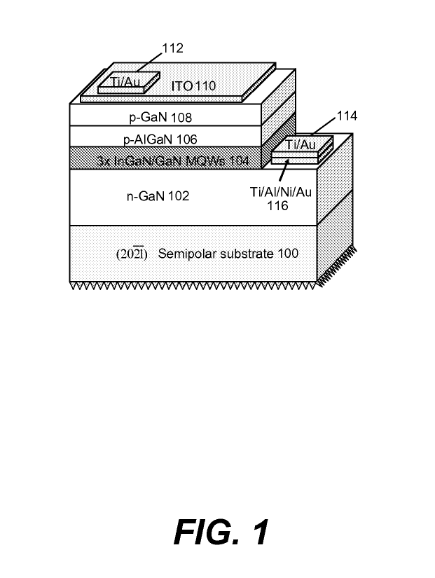

FIG. 1 is a schematic of a prototype LED device fabricated on a semipolar {20-2-1} substrate according to one embodiment of the present invention. Specifically, the prototype LED device was epitaxially grown on a semipolar {20-2-1} plane of a substrate 100. The substrate can be bulk III-nitride or a film of III-nitride, such as a semi-polar III-nitride template layer or epilayer grown heteroepitaxially on a foreign substrate, such as sapphire or silicon carbide or spinel.

The prototype LED device included an n-type GaN (n-GaN) layer 102, an active region 104 comprised of a 3×InGaN/GaN multiple quantum well (MQW) stack, a p-type AlGaN (p-AlGaN) electron blocking layer (EBL) 106, a p-type GaN (p-GaN) layer 108, an Indium-Tin-Oxide (ITO) layer 110, and two Ti/Au pads 112, 114 (a first pad 112 on the ITO layer 110 and a second pad 114 on the n-GaN layer 102), wherein the Ti/Au pad 114 on the n-GaN layer 102 resides on an Ti/Al/Ni/Au layer 116. These layers were fabricated using metal organic chemical vapor deposition (MOCVD), as well as conventional photolithography, dry-etching, and lift-off techniques. The backside of the (20-2-1) semipolar substrate 100 was roughened to have conical features, which improves the light extraction efficiency. The prototype LED device was then packaged with a transparent stand.

Process Steps

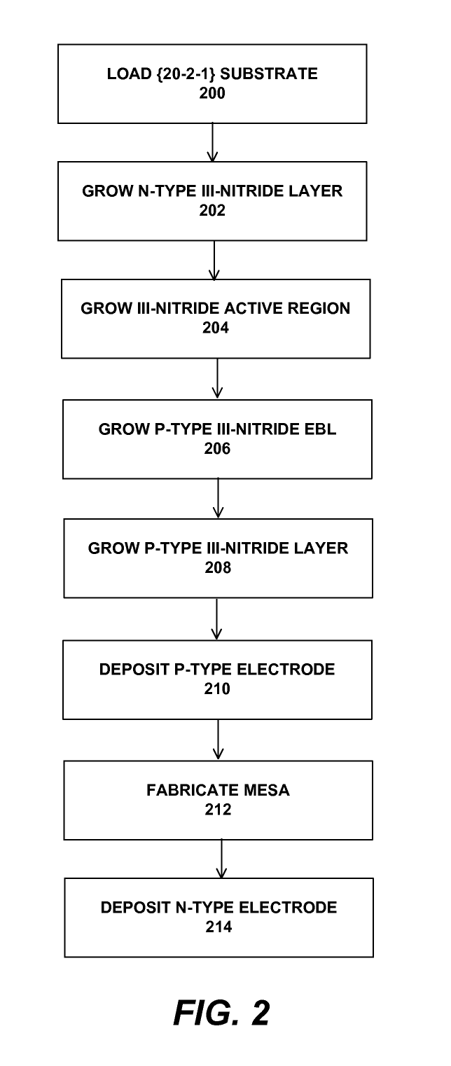

FIG. 2 is a flow chart that describes a method for fabricating the LED of FIG. 1 according to one embodiment of the present invention.

Block 200 represents a semipolar {20-2-1} substrate being loaded into a metal organic chemical vapor deposition (MOCVD) reactor. As noted above, the semipolar {20-2-1 } substrate can be bulk III-nitride or a film of III-nitride.

Block 202 represents the growth of an n-type III-nitride layer, e.g., Si doped n-GaN, on the substrate.

Block 204 represents the growth of a III-nitride active region, e.g., a 3x InGaN/GaN MQW structure, on the n-GaN layer.

Block 206 represents the growth of a p-type III-nitride EBL, e.g., Mg doped p-AlGaN, on the active region.

Block 208 represents the growth of a p-type III-nitride layer, e.g., Mg doped p-GaN, on the p-AlGaN EBL.

Block 210 represents the deposition of a transparent conducting oxide (TCO) layer, such as Indium-Tin-Oxide (ITO), as a p-type electrode on the p-GaN layer. Block 212 represents the fabrication of a mesa by patterning and etching.

Block 214 represents the deposition of a Ti/Al/Ni/Au layer on the n-GaN layer exposed by the mesa etch, followed by the deposition of an n-type electrode, such as Ti/Au, on the Ti/Al/Ni/Au layer.

Other steps not shown in FIG. 2 may also be performed, such as activation, annealing, dicing, mounting, bonding, encapsulating, packaging, etc.

The end result of these process steps is an optoelectronic device comprising an (Al,Ga,In)N LED grown on a semipolar {20-2-1} plane of a substrate.

Experimental Results

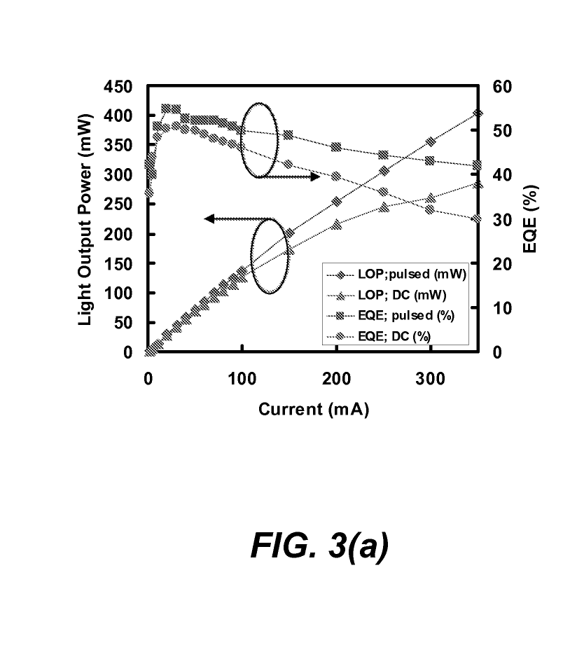

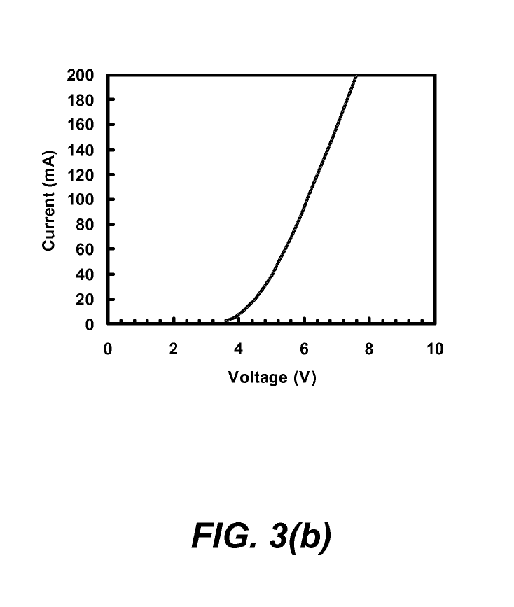

It has been determined, through experimental results, that this invention provides a blue light emitting LED on a {20-2-1} substrate that yields 30 mW light output power (LOP) and 54.7% external quantum efficiency (EQE) at a driving current of 20 mA, which are higher values than any other LEDs grown on existing nonpolar or semipolar planes, and are comparable to the best state-of-art c-plane devices. FIG. 3(a) is a graph of the L-I (light output power vs. current) and EQE-I (external quantum efficiency vs. current) characteristics of the prototype LED device of FIG. 1, under pulsed and DC operation.

FIG. 3(b) is a graph of I-V (current v. voltage) characteristics of the prototype LED device of FIG. 1. As shown in these Figures, the benefits of the present invention include improved LED performance.

Electroluminescence Intensity vs. Wavelength

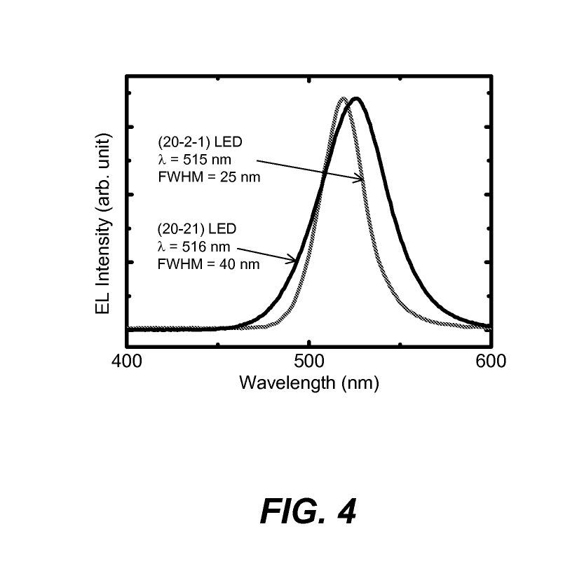

FIG. 4 is a graph of electroluminescence (EL) intensity (arbitrary units) vs. wavelength (nm), which shows the EL spectrum for single-quantum-well (SQW) LEDs grown on the {20-2-1} and {20-21} planes, respectively. These LEDs have identical structure. Due to the different Indium incorporation rate of these two planes, the QW of the {20-2-1} LED was grown at 30° C. higher than the QW of the {20-21} LED, so that these LEDs have same emission wavelength. At a wavelength of 515 nm, the {20-2-1} LED demonstrates a narrower spectrum than the {20-21} LED, by showing a full-width-at-half-maximum (FWHM) of 25 nm, while that for the {20-21} LED is almost twice as large, showing a FWHM of 40 nm. The narrow spectrum of the {20-2-1} LED is likely due to the higher InGaN quality caused by high Indium incorporation and high growth temperature observed on this plane. Since a narrow emission spectrum is highly desired for high performance LEDs and laser diodes (LDs), devices grown on the {20-2-1} plane are therefore advantageous for making optoelectronic devices having a higher performance than optoelectronic devices grown on other semipolar planes.

Advantages and Improvements

An (Al,Ga,In)N device grown on a semipolar {20-2-1} plane of a substrate is characterized by the following properties:
A narrower emission spectrum width,
A lower injection current dependent blue shift in its output peak emission wavelength,
An increased oscillator strength, leading to higher efficiency,
Better performance at long wavelengths,
Higher Indium incorporation rate at the same growth temperature, and
A thicker active region,
   as compared to an (Al,Ga,In)N device grown on other, different, semipolar planes.

In addition, the critical thickness of strained epitaxial (Al,Ga,In)N alloy layers grown on a semipolar {20-2-1} substrate is expected to be larger than other semipolar planes (i.e., {11-22}, {10-1-1}, etc.). This allows the use of a thicker active region structure, as compared to an (Al,Ga,In)N device grown on other, different, semipolar planes, which can reduce effective carrier density in quantum wells (reducing Auger-type losses and efficiency droop) and can facilitate low transparency carrier density.

Possible Modifications and Variations

Possible modifications and variations include the use of different fabrication techniques, as well as the fabrication of different LED structures. In addition, different packaging methods may be used as well. Moreover, other types of optoelectronic devices, such as laser diodes, lasers, solar cells, photodetectors, etc., may be fabricated using the present invention.

Future developments will include improvement of device performance, CW (continuous wave) operation, increased working wavelength, increased light output power and external quantum efficiency, reduced efficiency droop under large current operation, etc.

Nomenclature

The terms “III-nitride,” “Group-III nitride”, or “nitride,” as used herein refer to any alloy composition of the (Ga,Al,In,B)N semiconductors having the formula Ga_{w}AlₓIn_{y}B_{z}N where 0≦w≦1, 0≦x≦1, 0≦y≦1, 0≦z≦1, and w+x+y+z=1. These terms are intended to be broadly construed to include respective nitrides of the single species, Ga, Al, In and B, as well as binary, ternary and quaternary compositions of such Group III metal species. Accordingly, it will be appreciated that the discussion of the invention hereinafter in reference to GaN and InGaN materials is applicable to the formation of various other (Ga,Al,In,B)N material species. Further, (Ga,Al,In,B)N materials within the scope of the invention may further include minor quantities of dopants and/or other impurity or inclusional materials.

Many (Ga,Al,In,B)N devices are grown along the polar c-plane of the crystal, although this results in an undesirable quantum-confined Stark effect (QCSE), due to the existence of strong piezoelectric and spontaneous polarizations. One approach to decreasing polarization effects in (Ga,Al,In,B)N devices is to grow the devices on nonpolar or semipolar planes of the crystal.

The term “nonpolar plane” includes the {11-20} planes, known collectively as a-planes, and the {10-10} planes, known collectively as m-planes. Such planes contain equal numbers of gallium and nitrogen atoms per plane and are charge-neutral. Subsequent nonpolar layers are equivalent to one another, so the bulk crystal will not be polarized along the growth direction.

The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

Miller indices are a notation system in crystallography for planes and directions in crystal lattices, wherein the notation {h, i, k, l} denotes the set of all planes that are equivalent to (h, i, k, l) by the symmetry of the lattice. The use of braces, { }, denotes a family of symmetry-equivalent planes represented by parentheses, ( ), wherein all planes within a family are equivalent for the purposes of this invention.

### CONCLUSION

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
an (Al,Ga,In)N light emitting diode (LED) grown on a semipolar {20-2-1} plane.

2. The device of claim 1, wherein the (Al,Ga,In)N LED has a narrower emission spectrum width as compared to an (Al,Ga,In)N LED grown on other semipolar planes.

3. The device of claim 1, wherein the (Al,Ga,In)N LED has a lower injection current dependent blue shift in its output peak emission wavelength as compared to an (Al,Ga,In)N LED grown on other semipolar planes.

4. The device of claim 1, wherein the (Al,Ga,In)N LED has an increased oscillator strength, leading to higher efficiency, as compared to an (Al,Ga,In)N LED grown on other semipolar planes.

5. The device of claim 1, wherein the (Al,Ga,In)N LED has better performance at long wavelengths as compared to an (Al,Ga,In)N LED grown on other semipolar planes.

6. The device of claim 1, wherein the (Al,Ga,In)N LED has a higher Indium incorporation rate at the same growth temperature as compared to an (Al,Ga,In)N LED grown on other semipolar planes.

7. The device of claim 1, wherein the (Al,Ga,In)N LED has a thicker active region as compared to an (Al,Ga,In)N LED grown on other semipolar planes.

8. A method of fabricating an optoelectronic device, comprising:
growing an (Al,Ga,In)N light emitting diode (LED) on a semipolar {20-2-1} plane.

9. The method of claim 8, wherein the (Al,Ga,In)N LED has a narrower emission spectrum width as compared to an (Al,Ga,In)N LED grown on other semipolar planes.

10. The method of claim 8, wherein the (Al,Ga,In)N LED has a lower injection current dependent blue shift in its output peak emission wavelength as compared to an (Al,Ga,In)N LED grown on other semipolar planes.

11. The method of claim 8, wherein the (Al,Ga,In)N LED has an increased oscillator strength, leading to higher efficiency, as compared to an (Al,Ga,In)N LED grown on other semipolar planes.

12. The method of claim 8, wherein the (Al,Ga,In)N LED has better performance at long wavelengths as compared to an (Al,Ga,In)N LED grown on other semipolar planes.

13. The method of claim 8, wherein the (Al,Ga,In)N LED has a higher Indium incorporation rate at the same growth temperature as compared to an (Al,Ga,In)N LED grown on other semipolar planes.

14. The method of claim 8, wherein the (Al,Ga,In)N LED has a thicker active region as compared to an (Al,Ga,In)N LED grown on other semipolar planes.

15. A device fabricated using the method of claim 8.
